(19) United States
(12) Patent Application Publication
(10) Pub. No.: US 2026/0362803 A1
(43) Pub. Date: Nov. 12, 2026

(54) SEMICONDUCTOR DEVICE AND METHOD OF MANUFACTURING THE SAME

(71) Applicant: INSTITUTE OF MICROELECTRONICS, CHINESE ACADEMY OF SCIENCES, Beijing (CN)

(72) Inventors: Yongliang LI, Beijing (CN); Xin WANG, Beijing (CN); Haoyan LIU, Beijing (CN); Xiaolei WANG, Beijing (CN)

(21) Appl. No.: 19/283,345

(22) Filed: Jul. 29, 2025

(30) Foreign Application Priority Data
May 6, 2025 (CN) 202510578647.0

(51) Int. Cl. H10D 84/85; H10D 84/01

(52) U.S. Cl. CPC H10D 84/856; H10D 84/0167; H10D 84/0188; H10D 84/851

(57) ABSTRACT

A semiconductor device and a method of manufacturing a semiconductor device are provided. The semiconductor device includes: a semiconductor substrate and a first transistor disposed on the semiconductor substrate. The first transistor includes a gate stack surrounding a periphery of a channel region which includes at least one semiconductor structure. In a width direction of the channel region, each semiconductor structure includes at least two first semiconductor portions and a second semiconductor portion between every two adjacent first semiconductor portions. In the semiconductor structure, at least one of surfaces of the second semiconductor portion distributed oppositely in a thickness direction of the semiconductor substrate is recessed inward relative to a corresponding one of surfaces of the first semiconductor portion distributed oppositely in the thickness direction of the semiconductor substrate. Each of the first and second semiconductor portions is in contact with source and drain regions of the first transistor.

### CROSS-REFERENCE TO RELATED APPLICATIONS

This application is claims priority to Chinese Application No. 202510578647.0 filed on May 6, 2025, which is incorporated herein by reference in its entirety.

### TECHNICAL FIELD

The present disclosure relates to a field of semiconductor technology, and in particular to a semiconductor device and a method of manufacturing a semiconductor device.

### BACKGROUND

A gate-all-around transistor includes a gate stack formed not only on a top portion and a sidewall of at least one layer of nanostructure, but also on a bottom portion of the at least one layer of nanostructure. Therefore, compared with a planar transistor and a fin field-effect transistor, the gate-all-around transistor has advantages such as a high gate control capability. In view of this, when the transistor in semiconductor device is a gate-all-around transistor, a working performance of the semiconductor device may be improved.

However, a channel region included in an existing gate-all-around transistor has poor conduction characteristics, which limits further improving the working performance of the semiconductor device.

### SUMMARY

The present disclosure provides a semiconductor device and a method of manufacturing a semiconductor device.

In a first aspect, the present disclosure provides a semiconductor device, including: a semiconductor substrate and a first transistor disposed on the semiconductor substrate. The first transistor includes a gate stack surrounding a periphery of a channel region. The channel region includes at least one semiconductor structure. In a width direction of the channel region, each semiconductor structure includes at least two first semiconductor portions arranged at intervals and a second semiconductor portion disposed between every two adjacent first semiconductor portions. In the semiconductor structure, at least one of surfaces of the second semiconductor portion distributed oppositely in a thickness direction of the semiconductor substrate is recessed inward relative to a corresponding one of surfaces of the first semiconductor portion distributed oppositely in the thickness direction of the semiconductor substrate. In a length direction of the channel region, each of the first semiconductor portion and the second semiconductor portion is in contact with a source region and a drain region included in the first transistor.

In an example, a height of the first semiconductor portion is greater than a height of the second semiconductor portion; and/or a width of the second semiconductor portion is greater than a width of the first semiconductor portion.

In an example, a crystal orientation of the first semiconductor portion is a crystal orientation; and/or a crystal orientation of the second semiconductor portion is a crystal orientation; and/or the first transistor is a P-type transistor.

In an example, in the semiconductor structure, the second semiconductor portion is suspended between every two adjacent first semiconductor portions; and/or the semiconductor structure is H-shaped.

In an example, in a case that the channel region includes a plurality of semiconductor structures, different semiconductor structures are distributed at intervals in the thickness direction of the semiconductor substrate. The gate stack surrounds a periphery of each semiconductor structure.

In an example, the semiconductor device further includes a second transistor and a first isolation structure. The first transistor and the second transistor are distributed at interval in the thickness direction of the semiconductor substrate. The first isolation structure is disposed between the source region included in the first transistor and a source region included in the second transistor and between the drain region included in the first transistor and a drain region included in the second transistor, respectively.

In an example, in the width direction of the channel region, at least the semiconductor structure located at bottom of the first transistor has a sidewall substantially aligned with a sidewall of a channel region included in the second transistor.

In a second aspect, the present disclosure provides a method of manufacturing a semiconductor device, including: forming a first fin structure on a semiconductor substrate. The first fin structure includes at least a first sacrificial layer and a first channel layer located on the first sacrificial layer. Then, a first mask is formed on sidewalls of the first fin structure to surround a periphery of the first fin structure. Then, at least edge portions on both sides of the first fin structure in a width direction of the first fin structure are selectively removed, so as to form an open trench. The open trench penetrates through at least the first channel layer, and at least part of the first sacrificial layer with reduced thickness is retained at bottom of the open trench. Then, a first semiconductor portion is formed in the open trench. A portion of the first channel layer remaining between two adjacent first semiconductor portions acts as a second semiconductor portion. Then, a first transistor is formed based on the first fin structure and the first semiconductor portion. The first transistor includes a gate stack surrounding a periphery of a channel region. The channel region includes at least one semiconductor structure, and each semiconductor structure includes the first semiconductor portion and the second semiconductor portion. In the semiconductor structure, at least one of surfaces of the second semiconductor portion distributed oppositely in a thickness direction of the semiconductor substrate is recessed inward relative to a corresponding one of surfaces of the first semiconductor portion distributed oppositely in the thickness direction of the semiconductor substrate. Each of the first semiconductor portion and the second semiconductor portion is in contact with a source region and a drain region included in the first transistor.

In an example, the first fin structure further includes a second sacrificial layer located on the first channel layer. After selectively removing at least the edge portions on both sides of the first fin structure in the width direction, the open trench further penetrates through the second sacrificial layer.

In an example, the method of manufacturing a semiconductor device further includes: in a case that the channel region includes a plurality of semiconductor structures, before forming a first transistor based on a remaining portion of the first fin structure and the first semiconductor portion, repeating an operation of sequentially forming the first fin structure, the first mask, the open trench and the first semiconductor portion until a number of layers of first semiconductor portions formed on the semiconductor substrate is equal to a number of layers of the semiconductor structures in the channel region. Two adjacent layers of the first semiconductor portions are spaced by a portion of the first sacrificial layer with reduced thickness.

In an example, the forming a first transistor based on the first fin structure and the first semiconductor portion includes: selectively removing at least part of the first mask in a thickness direction of the first mask, so as to expose a bottom portion of the first sacrificial layer; forming a second mask structure spanning the first fin structure; selectively removing a portion of the first fin structure and a portion of the first semiconductor portion exposed from the second mask structure, and forming the source region and the drain region included in the first transistor on both sides of a remaining portion of the first fin structure and a remaining portion of the first semiconductor portion, respectively; selectively removing at least part of the second mask structure, and removing at least a remaining portion of the first sacrificial layer, so that the remaining portion of the first semiconductor portion and the second semiconductor portion form the channel region; and forming the gate stack surrounding the periphery of the channel region.

In an example, a second fin structure and a semiconductor isolation structure are formed on the semiconductor substrate while forming the first fin structure on the semiconductor substrate. In the thickness direction of the semiconductor substrate, the semiconductor isolation structure and the first fin structure are sequentially disposed on the second fin structure. The method of manufacturing the semiconductor device further includes: forming a second transistor based on the second fin structure; and forming a first isolation structure between the source region included in the first transistor and a source region included in the second transistor and between the drain region included in the first transistor and a drain region included in the second transistor, respectively.

### BRIEF DESCRIPTION OF THE DRAWINGS

Accompanying drawings described herein are used to provide a further understanding of the present disclosure and constitute a part of the present disclosure. Schematic embodiments of the present disclosure and the descriptions thereof are used to explain the present disclosure and do not constitute an improper limitation to the present disclosure, in which:

FIG. 1 is a first schematic structural diagram of a semiconductor device during a manufacturing process provided in embodiments of the present disclosure.

FIG. 2 is a second schematic structural diagram of a semiconductor device during a manufacturing process provided in embodiments of the present disclosure.

FIG. 3 is a third schematic structural diagram of a semiconductor device during a manufacturing process provided in embodiments of the present disclosure.

FIG. 4 is a fourth schematic structural diagram of a semiconductor device during a manufacturing process provided in embodiments of the present disclosure.

FIG. 5 is a fifth schematic structural diagram of a semiconductor device during a manufacturing process provided in embodiments of the present disclosure.

FIG. 6 is a sixth schematic structural diagram of a semiconductor device during a manufacturing process provided in embodiments of the present disclosure.

FIG. 7 is a seventh schematic structural diagram of a semiconductor device during a manufacturing process provided in embodiments of the present disclosure.

FIG. 8 is an eighth schematic structural diagram of a semiconductor device during a manufacturing process provided in embodiments of the present disclosure.

FIG. 9 is a ninth schematic structural diagram of a semiconductor device during a manufacturing process provided in embodiments of the present disclosure.

FIG. 10 is a tenth schematic structural diagram of a semiconductor device during a manufacturing process provided in embodiments of the present disclosure.

FIG. 11 is an eleventh schematic structural diagram of a semiconductor device during a manufacturing process provided in embodiments of the present disclosure.

FIG. 12 is a twelfth schematic structural diagram of a semiconductor device during a manufacturing process provided in embodiments of the present disclosure.

FIG. 13 is a thirteenth schematic structural diagram of a semiconductor device during a manufacturing process provided in embodiments of the present disclosure.

FIG. 14 is a fourteenth schematic structural diagram of a semiconductor device during a manufacturing process provided in embodiments of the present disclosure.

FIG. 15 is a fifteenth schematic structural diagram of a semiconductor device during a manufacturing process provided in embodiments of the present disclosure.

FIG. 16 is a sixteenth schematic structural diagram of a semiconductor device during a manufacturing process provided in embodiments of the present disclosure.

FIG. 17 is a seventeenth schematic structural diagram of a semiconductor device during a manufacturing process provided in embodiments of the present disclosure.

FIG. 18 is an eighteenth schematic structural diagram of a semiconductor device during a manufacturing process provided in embodiments of the present disclosure.

FIG. 19 is a nineteenth schematic structural diagram of a semiconductor device during a manufacturing process provided in embodiments of the present disclosure.

FIG. 20 is a twentieth schematic structural diagram of a semiconductor device during a manufacturing process provided in embodiments of the present disclosure.

FIG. 21 illustrates a twenty-first schematic structural diagram and a twenty-second schematic structural diagram of a semiconductor device at a second semiconductor portion and a first semiconductor portion during a manufacturing process provided in embodiments of the present disclosure, with the twenty-first schematic structural diagram being shown as part (1) and the twenty-second schematic structural diagram being shown as part (2).

FIG. 22 illustrates a twenty-third schematic structural diagram and a twenty-fourth schematic structural diagram of a semiconductor device at a second semiconductor portion and a first semiconductor portion during a manufacturing process provided in embodiments of the present disclosure, with the twenty-third schematic structural diagram being shown as part (1) and the twenty-fourth schematic structural diagram being shown as part (2).

FIG. 23 illustrates a twenty-fifth schematic structural diagram and a twenty-sixth schematic structural diagram of a semiconductor device at a second semiconductor portion and a first semiconductor portion during a manufacturing process provided in embodiments of the present disclosure, with the twenty-fifth schematic structural diagram being shown as part (1) and the twenty-sixth schematic structural diagram being shown as part (2).

FIG. 24 illustrates a twenty-seventh schematic structural diagram and a twenty-eighth schematic structural diagram of a semiconductor device at a second semiconductor portion and a first semiconductor portion during a manufacturing process provided in embodiments of the present disclosure, with the twenty-seventh schematic structural diagram being shown as part (1) and the twenty-eighth schematic structural diagram being shown as part (2).

FIG. 25 illustrates a twenty-ninth schematic structural diagram and a thirtieth schematic structural diagram of a semiconductor device at a second semiconductor portion and a first semiconductor portion during a manufacturing process provided in embodiments of the present disclosure, with the twenty-ninth schematic structural diagram being shown as part (1) and the thirtieth schematic structural diagram being shown as part (2).

FIG. 26 is a thirty-first schematic structural diagram of a semiconductor device during a manufacturing process provided in embodiments of the present disclosure.

FIG. 27 is a thirty-second schematic structural diagram of a semiconductor device during a manufacturing process provided in embodiments of the present disclosure.

FIG. 28 is a thirty-third schematic structural diagram of a semiconductor device during a manufacturing process provided in embodiments of the present disclosure.

### REFERENCE NUMERALS

11 represents a semiconductor substrate, 12 represents a first transistor, 13 represents a gate stack, 14 represents a channel region, 15 represents a semiconductor structure, 16 represents a first semiconductor portion, 17 represents a second semiconductor portion, 18 represents a source region, 19 represents a drain region, 20 represents a second transistor, 21 represents a first isolation structure, 22 represents a first fin structure, 23 represents a first sacrificial layer, 24 represents a first sacrificial layer, 25 represents a first mask, 26 represent an open trench, 27 represents a second sacrificial layer, 28 represents a second mask structure, 29 represents a second fin structure, 30 represents a semiconductor isolation structure, 31 represents a second isolation structure, 32 represents a third sacrificial layer, 33 represents a second channel layer, and 34 represents an insulating dielectric layer.

### DETAILED DESCRIPTION OF EMBODIMENTS

Embodiments of the present disclosure will be described below with reference to the accompanying drawings. It should be understood, however, that these descriptions are merely exemplary and are not intended to limit the scope of the present disclosure. In addition, in the following descriptions, descriptions of well-known structures and technologies are omitted to avoid unnecessarily obscuring the concept of the present disclosure.

Various schematic structural diagrams according to embodiments of the present disclosure are shown in the accompanying drawings. The drawings are not drawn to scale. Some details are enlarged and some details may be omitted for clarity of presentation. Shapes of the various regions, layers as well as a relative size and a positional relationship thereof shown in the drawings are only exemplary. In practice, there may be deviations due to manufacturing tolerances or technical limitations, and those skilled in the art may additionally design regions/layers with different shapes, sizes, and relative positions according to practical requirements.

In the context of the present disclosure, when a layer/element is referred to as being located “on” another layer/element, the layer/element may be directly on the another layer/element, or there may be an intermediate layer/element therebetween. In addition, if a layer/element is located “on” another layer/element in one orientation, the layer/element may be located “under” the another layer/element when the orientation is reversed. In order to make the technical problems, technical solutions and beneficial effects to be solved by the present disclosure clearer, the present disclosure will be further described in detail with the accompanying drawings and embodiments. It should be understood that specific embodiments described herein are just used to explain the present disclosure, and are not intended to limit the present disclosure.

In addition, terms “first” and “second” are only used for descriptive purposes and are not to be construed as indicating or implying a relative importance or implicitly indicating the number of indicated technical features. Thus, features defined by “first” and “second” may explicitly or implicitly include one or more of the features. In the descriptions of embodiments of the present disclosure, unless otherwise specified, a term “plurality” means two or more. “Several” means one or more, unless otherwise specified.

In the description of the present disclosure, it should be noted that unless otherwise specified and limited, terms “installation”, “coupling” and “connection” should be understood in broad sense. For example, a connection may be a fixed connection, a detachable connection or an integrated connection; it may also be a mechanical connection or an electrical connection; it may also be a direct connection, or may also be an indirect connection through an intermediation, which may be an internal communication between two elements or an interaction relationship between two elements. For those skilled in the art, the specific meanings of the above-mentioned terms in the present disclosure may be understood according to specific circumstances.

A gate-all-around transistors includes a gate stack formed not only on a top portion and a sidewall of at least one layer of nanostructure, but also on a bottom portion of the at least one layer of nanostructure. Therefore, compared with a planar transistor and a fin field-effect transistor, the gate-all-around transistor has advantages such as a high gate control capability, etc. In view of this, when a transistor of a semiconductor device is a gate-all-around transistor, a working performance of the semiconductor device may be improved.

However, a channel region included in an existing gate-all-around transistor has poor conduction characteristics, which limits further improving the working performance of the semiconductor device.

Embodiments of the present disclosure provide a semiconductor device and a method of manufacturing a semiconductor device, in order to increase a conduction area of a channel region and improve conduction characteristics of the channel region, which is beneficial to improving a working performance of the semiconductor device. In the semiconductor device provided in embodiments of the present disclosure, each semiconductor structure included in the channel region not only includes a second semiconductor portion, but further includes at least two first semiconductor portions arranged at intervals in a width direction of the channel region, the second semiconductor portion is adjacent to two adjacent first semiconductor portions, and at least one of surfaces of the second semiconductor portion distributed oppositely in a thickness direction of a semiconductor substrate is recessed inward relative to a corresponding one of surfaces of the first semiconductor portion distributed oppositely in the thickness direction of the semiconductor substrate, so as to increase a conduction area of a channel region and improve conduction characteristics of the channel region, which is beneficial to improving the working performance of the semiconductor device.

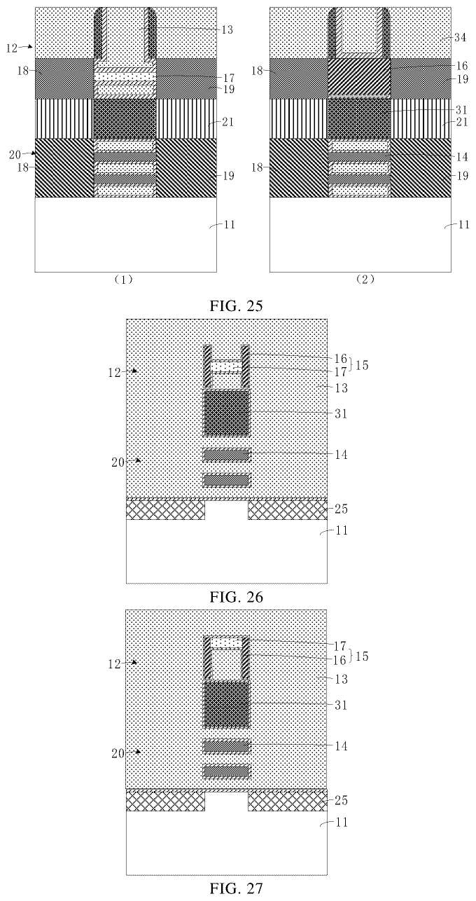

In a first aspect, embodiments of the present disclosure provide a semiconductor device. As shown in FIG. 25 to FIG. 28, the semiconductor device includes: a semiconductor substrate 11 and a first transistor 12 disposed on the semiconductor substrate 11. The first transistor 12 includes a gate stack 13 surrounding a periphery of a channel region 14. The channel region 14 includes at least one semiconductor structure 15. In a width direction of the channel region 14, each semiconductor structure 15 includes at least two first semiconductor portions 16 arranged at intervals and a second semiconductor portion 17 disposed between every two adjacent first semiconductor portions 16. In the semiconductor structure 15, at least one of surfaces of the second semiconductor portion 17 distributed oppositely in a thickness direction of the semiconductor substrate 11 is recessed inward relative to a corresponding one of surfaces of the first semiconductor portion 16 distributed oppositely in the thickness direction of the semiconductor substrate 11. In a length direction of the channel region 14, each of the first semiconductor portion 16 and the second semiconductor portion 17 is in contact with a source region 18 and a drain region 19 included in the first transistor 12.

In this way, as shown in FIG. 25 to FIG. 28, the first transistor 12 is disposed on the semiconductor substrate 11. The gate stack 13 included in the first transistor 12 surrounds the periphery of the channel region 14. It can been seen that the first transistor 12 is a gate-all-around transistor, which has a high gate control capability and is beneficial to suppressing a short-channel effect. In addition, compared with a conventional channel region only including a single-layer or multi-layer nanowire/nanosheet, in the semiconductor device provided in embodiments of the present disclosure, each semiconductor structure 15 included in the channel region 14 includes at least two first semiconductor portions 16 arranged at intervals in the width direction of the channel region 14, in addition to the second semiconductor portion 17. The second semiconductor portion 17 is adjacent to two adjacent first semiconductor portions 16, and the at least one of surfaces of the second semiconductor portion 17 distributed oppositely in the thickness direction of the semiconductor substrate 11 is recessed inward relative to a corresponding one of surfaces of the first semiconductor portion 16 distributed oppositely in the thickness direction of the semiconductor substrate 11. Therefore, in the two surfaces of the first semiconductor portion 16 distributed oppositely in the channel region 14 in the width direction of the channel region 14, a surface in contact with the second semiconductor portion 17 has a portion exposed from the second semiconductor portion 17, which may also be covered by the gate stack 13, and each of the first semiconductor portion 16 and the second semiconductor portion 17 is in contact with the source region 18 and the drain region 19 included in the first transistor, so as to increase a conduction area of the channel region 14, improve conduction characteristics of the channel region 14, and further improve a driving performance of the first transistor 12, which is beneficial to improving the working performance of the semiconductor device.

In an actual application, the semiconductor substrate may be a silicon substrate, a germanium silicon substrate, a germanium substrate, a silicon-on-insulator substrate or the like without any structure formed thereon.

For example, the above-mentioned semiconductor substrate may also be a semiconductor substrate on which some structures are formed. For example, in a case that the first transistor included in the semiconductor device provided in embodiments of the present disclosure is applied to a transistor located at a second layer or a higher layer in an integrated circuit, the above-mentioned semiconductor substrate may include a semiconductor substrate, a lower-layer device formed on the semiconductor substrate, an interlayer dielectric layer for isolating the lower-layer device, or the like.

As for the first transistor, in terms of conductivity type, the first transistor may be a P-type transistor or an N-type transistor.

In terms of structure, as shown in FIG. 25 to FIG. 28, the source region 18 and the drain region 19 included in the first transistor 12 are distributed at intervals in a direction parallel to a surface of the semiconductor substrate 11. The channel region 14 is disposed between the source region 18 and the drain region 19. The gate stack 13 surrounds the periphery of the channel region 14.

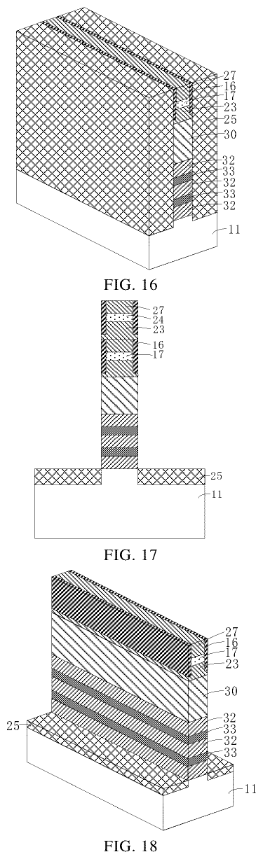

Specifically, as shown in FIG. 25 to FIG. 28, the channel region 14 may include one semiconductor structure 15. Alternatively, as shown in FIG. 16, the channel region 14 may also include a plurality of semiconductor structures 15, different semiconductor structures 15 are distributed at intervals in the thickness direction of the semiconductor substrate 11, and the gate stack 13 surrounds a periphery of each semiconductor structure 15.

As shown in FIG. 25 to FIG. 28, in the width direction of the channel region 14, each semiconductor structure 15 may only include two first semiconductor portions 16 arranged at intervals and a second semiconductor portion 17 disposed between two adjacent first semiconductor portions 16. Alternatively, each semiconductor structure may also include a plurality of first semiconductor portions arranged at intervals in the width direction of the channel region, and a second semiconductor portion disposed between every two adjacent first semiconductor portions. When the channel region 14 includes a plurality of semiconductor structures 15 distributed at intervals in the thickness direction of the semiconductor substrate 11, different semiconductor structures 15 may include the same or different numbers of first semiconductor portions.

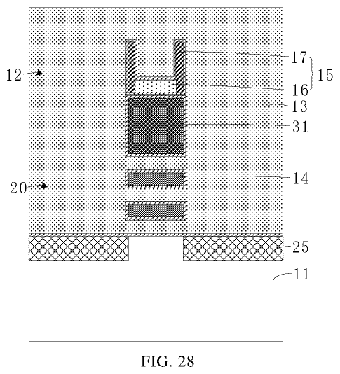

In addition, as shown in FIG. 27 and FIG. 28, in a single semiconductor structure 15, one of the surfaces of the second semiconductor portion 17 distributed oppositely in the thickness direction of the semiconductor substrate 11 may be recessed inward relative to a corresponding one of surfaces of the first semiconductor portion 16 distributed oppositely in the thickness direction of the semiconductor substrate 11. In this case, the second semiconductor portion 17 may be disposed on top of the two adjacent first semiconductor portions 16 in the thickness direction of the semiconductor substrate 11, that is, a bottom surface of the second semiconductor portion 17 is recessed inward (upward) relative to bottom surfaces of the two adjacent first semiconductor portions 16. As another example, the second semiconductor portion 17 may be disposed at bottom of two adjacent first semiconductor portions 16 in the thickness direction of the semiconductor substrate 11, that is, a top surface of the second semiconductor portion 17 is recessed inward (downward) relative to top surfaces of the two adjacent first semiconductor portions 16. In addition, in the thickness direction of the semiconductor substrate 11, in a same semiconductor structure 15, the two adjacent first semiconductor portions 16 may be substantially aligned on both sides, or may be staggered by a certain distance (a size of the distance may be set according to practical requirements, and will not be specifically limited here).

Alternatively, as shown in FIG. 26, in a single semiconductor structure 15, two surfaces of the second semiconductor portion 17 distributed oppositely in the thickness direction of the semiconductor substrate 11 may be recessed inward relative to corresponding surfaces of the first semiconductor portion 16 distributed oppositely in the thickness direction of the semiconductor substrate 11. In this case, in the semiconductor structure 15, the second semiconductor portion 17 may be suspended between every two adjacent first semiconductor portions 16. The single semiconductor structure 15 may have a quasi-H shape. The quasi-H shape refers to a regular H morphology or a morphology that is substantially the same as an H shape.

In terms of size, the size of the first semiconductor portion and the size of the second semiconductor portion in the same semiconductor structure may be set according to a conductivity type of the first transistor and practical requirements, and will not be specifically limited here.

For example, as shown in FIG. 25 to FIG. 28, a height of the first semiconductor portion 16 may be greater than a height of the second semiconductor portion 17, so as to further increase the conduction area of the channel region 14 and improve the driving performance of the first transistor 12.

For example, as shown in FIG. 25 to FIG. 28, a width of the second semiconductor portion 17 may be greater than a width of the first semiconductor portion 16, so as to further increase the conduction area of the channel region 14 and improve the driving performance of the first transistor 12.

In an example, as shown in FIG. 25 to FIG. 28, a crystal orientation of the first semiconductor portion 16 may be a [110] crystal orientation; and/or, a crystal orientation of the second semiconductor portion 17 is a [100] crystal orientation. In view of this, when the first transistor 12 is a P-type transistor, channel carriers of the first transistor 12 are holes. Compared to the [100] crystal-oriented channel region 14 in conventional gate-all-around transistors, the [110] crystal-oriented first semiconductor portion 16 facilitates hole transport, thereby enhancing carrier transport efficiency in the channel region 14. Moreover, the presence of the [100]-oriented second semiconductor portion 17 may increase the conduction area of the channel region 14, thereby enhancing the drive capability of the first transistor 12. When the first transistor 12 is an N-type transistor with electrons as channel carriers, the [100]-oriented second semiconductor portion 17 facilitates electron transport, consequently improving carrier transport efficiency in the channel region 14. Meanwhile, the existence of the [110]-oriented first semiconductor portion 16 may enlarge the conduction area of the channel region 14, improving the drive performance of the first transistor 12.

In terms of material, each of the source region, the drain region and the channel region may include any semiconductor material, as long as the materials may be applied to the semiconductor device provided in embodiments of the present disclosure. In the channel region, a material of the first semiconductor portion included in the same semiconductor structure may be the same as or different from a material of the second semiconductor portion. In different semiconductor structures, different first semiconductor portions may have the same or different materials; and different second semiconductor portions may have the same or different materials.

As shown in FIG. 25 to FIG. 28, the gate stack 13 surrounds the periphery of the channel region 14. The gate stack 13 may include a gate dielectric layer and a gate electrode located on the gate dielectric layer. The gate dielectric layer surrounds the periphery of each semiconductor structure 15 and is formed on a portion of the semiconductor substrate 11 corresponding to a region in which the gate electrode is formed. A material of the gate dielectric layer may be an insulating material such as HfO₂, ZrO₂, TiO₂ or Al₂O₃. A material of the gate electrode may be a conductive material such as TiN, TaN or TiSiN.

In an example, as shown in parts (1) and (2) of FIG. 25, the first transistor 12 may further include a gate spacer, and the gate spacer is disposed at least on both sides of the gate stack 13 in a length direction, so as to facilitate a formation of the gate stack 13, and electrically isolates the gate stack 13 from other conductive structures, thereby improving an electrical reliability of the semiconductor device. A material of the gate spacer may include any insulating dielectric material such as silicon oxide, silicon nitride or silicon oxynitride, as long as the material may be applied to the semiconductor device provided in embodiments of the present disclosure.

In an example, as shown in FIG. 25 to FIG. 28, the semiconductor device may further include a second transistor 20 and a first isolation structure 21. The first transistor 12 and the second transistor 20 are distributed at interval in the thickness direction of the semiconductor substrate 11. The first isolation structure 21 is disposed between the source region 18 included in the first transistor 12 and the source region 18 included in the second transistor 20 and between the drain region 19 included in the first transistor 12 and the drain region 19 included in the second transistor 20, respectively. In this case, the first transistor 12 and the second transistor 20 may form a CFET device, thereby improving an integration of the semiconductor device.

Conductivity type of the first transistor may be the same as or different from the conductivity type of the second transistor.

In terms of setting position, in the thickness direction of the semiconductor substrate, the first transistor may be located above the second transistor. Alternatively, the second transistor may be located above the first transistor. The source region included in the second transistor may be located on the same side as the source region included in the first transistor in a length direction of the gate stack. Alternatively, the drain region included in the second transistor may be located on the same side as the source region included in the first transistor in the length direction of the gate stack.

As shown in FIG. 25 to FIG. 28, in the width direction of the channel region 14, at least the semiconductor structure 1 located at bottom of the first transistor 12 has a sidewall substantially aligned with a sidewall of the channel region 14 included in the second transistor 20. Alternatively, in the width direction of the channel region 14, the sidewall of at least one layer of semiconductor structure 15 included in the first transistor 12 may be staggered from a sidewall of the channel region 14 included in the second transistor 20.

The device type and structure of the second transistor will not be specifically limited in embodiments of the present disclosure, as long as the second transistor may be formed on the semiconductor substrate. For example, the second transistor may be a fin field-effect transistor or a gate-all-around transistor.

For the first isolation structure, a material and a thickness of the first isolation structure will not be specifically limited in embodiments of the present disclosure, as long as the first isolation structure may electrically isolate the source region and the drain region included in the second transistor from the source region and the drain region included in the first transistor.

For example, as shown in FIG. 25 to FIG. 28, the semiconductor device may further include a second isolation structure 31. The second isolation structure 31 is disposed between the gate stack 13 included in the first transistor 12 and the gate stack 13 included in the second transistor 20. The second isolation structure 31 may include any non-conductive isolation material such as silicon oxide, silicon nitride or silicon oxynitride.

In an example, as shown in FIG. 25 to FIG. 28, the semiconductor device may further include a shallow trench isolation structure and/or an insulating dielectric layer 34. The shallow trench isolation structure is formed on the semiconductor substrate 11 and is used to define an active region of the semiconductor substrate 11, so as to reduce a risk of leakage and further improve a yield and a working performance of the semiconductor device. The shallow trench isolation structure may include any insulating material such as silicon oxide, silicon oxynitride or silicon oxynitride, which will not be specifically limited here. The insulating dielectric layer 34 covers the first transistor 12 (when the semiconductor device further includes the second transistor 20, the insulating dielectric layer 34 covers the upper one of the first transistor 12 and the second transistor 20). The top of the insulating dielectric layer 34 is flush with the top of the gate stack 13 included in the first transistor 12 (when the semiconductor device further includes the second transistor 20, the top of the insulating dielectric layer 34 is flush with the top of the gate stack 13 included in the upper one of the first transistor 12 and the second transistor 20), so as to protect the source region 18 and the drain region 19 from an influence of etching and cleaning operations for removing at least part of the second mask structure, thereby improving the yield of the semiconductor device. The insulating dielectric layer 34 may include any insulating material such as silicon oxide, silicon oxynitride or silicon oxynitride, and will not be specifically limited here.

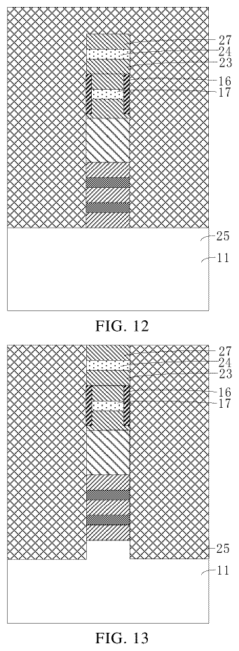

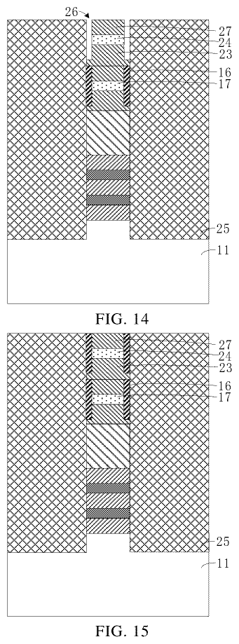

In a second aspect, embodiments of the present disclosure provide a method of manufacturing a semiconductor device. A manufacturing process will be described below with reference to perspective views or cross-sectional views of the operations shown in FIG. 1 to FIG. 28. Specifically, the method of manufacturing a semiconductor device includes the steps as follows.

First, as shown in FIG. 1 to FIG. 3, a first fin structure 22 is formed on the semiconductor substrate 11. The first fin structure 22 includes at least a first sacrificial layer 23 and a first channel layer 24 located on the first sacrificial layer 23.

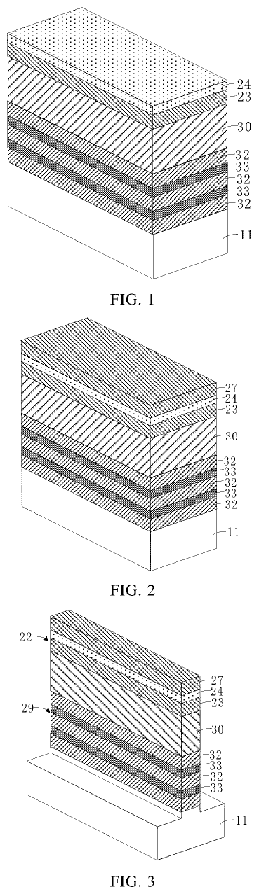

It may be understood that the first fin structure is at least used to manufacture the channel region included in the first transistor. Therefore, a specific structure of the first fin structure may be determined according to the number of layers of semiconductor structures included in the channel region and a specific morphology of each layer of semiconductor structure. As shown in FIG. 1, the first fin structure may include the first sacrificial layer 23 and the first channel layer 24. Alternatively, as shown in FIG. 2 and FIG. 3, the first fin structure 22 further includes a second sacrificial layer 27 located on the first channel layer 24.

For example, as shown in FIG. 1 and FIG. 27, in the manufactured semiconductor device, within a single semiconductor structure 15, if the second semiconductor portion 17 is disposed on top portions of the two adjacent first semiconductor portions 16 in the thickness direction of the semiconductor substrate 11, the first fin structure 22 may include the first sacrificial layer 23 and the first channel layer 24. In this case, for a material of the first channel layer 24, reference may be made to the material of the second semiconductor portion 17. A thickness of the first sacrificial layer 23 may be determined according to a thickness of the gate stack 13 and requirements for releasing the semiconductor structure 15 in an actual manufacturing process. A material of the first sacrificial layer 23 may be any semiconductor material different from the material of the first channel layer 24.

For example, as shown in FIG. 2, FIG. 3 and FIG. 28, if the second semiconductor portion 17 is disposed at the bottom portions of the two adjacent first semiconductor portions 16 in the thickness direction of the semiconductor substrate 11, the first fin structure 22 includes the first sacrificial layer 23, the first channel layer 24 and the second sacrificial layer 27 that are sequentially stacked. For the materials of the first channel layer 24 and the first sacrificial layer 23, reference may be made to the above description. A material of the second sacrificial layer 27 may be any semiconductor material different from the material of the first channel layer 24. The material of the second sacrificial layer 27 may be the same as or different from the material of the first sacrificial layer 23.

For example, as shown in FIG. 2, FIG. 3 and FIG. 26, if two surfaces of the second semiconductor portion 17 distributed oppositely in the thickness direction of the semiconductor substrate 11 are both recessed inward relative to corresponding surfaces of the first semiconductor portion 16 distributed oppositely in the thickness direction of the semiconductor substrate 11, the first fin structure 22 includes the first sacrificial layer 23, the first channel layer 24 and the second sacrificial layer 27 that are sequentially stacked. For the materials of the first channel layer 24, the first sacrificial layer 23 and the second sacrificial layer 27, reference may be made to the above description.

In an actual manufacturing process, as shown in FIG. 1 and FIG. 2, at least the first sacrificial layer 23 and the first channel layer 24 may be formed on the semiconductor substrate 11 by processes such as epitaxy according to a distribution of different film layers in the first fin structure 22. Next, as shown in FIG. 3, at least the first sacrificial layer 23, the first channel layer 24, and the semiconductor substrate 11 may be selectively etched by processes such as photolithography and etching, so as to form the first fin structure 22.

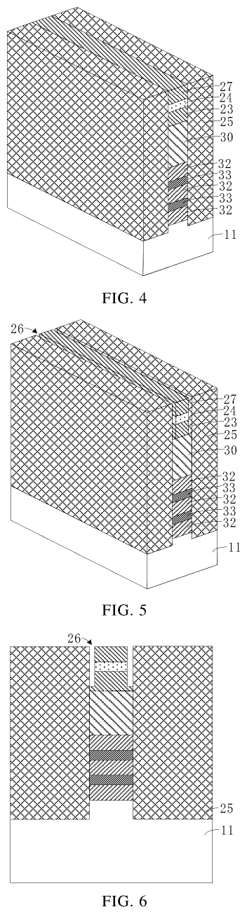

Next, as shown in FIG. 4, the first mask 25 surrounding a periphery of sidewalls of the first fin structure 22 may be formed by processes such as deposition and planarization.

A material of the first mask will not be specifically limited in embodiments of the present disclosure, as long as the material may be applied to the manufacturing method provided in embodiments of the present disclosure. For example, the first mask may include an insulating material used to manufacture a shallow trench isolation structure, so that the shallow trench isolation structure may be formed at the same time, thereby improving a manufacturing efficiency of the semiconductor device and reducing a manufacturing cost of the semiconductor device.

Next, as shown in FIG. 5, under a protection of the first mask 25, at least edge portions on both sides of the first fin structure 22 in a width direction are selectively removed by processes such as photolithography and etching, so as to form an open trench 26. The open trench 26 at least penetrates through the first channel layer 24, and at least part of the first sacrificial layer 23 with reduced thickness is retained at bottom of the open trench 26.

In the manufactured semiconductor device, if a single semiconductor structure includes two first semiconductor portions, the edge portions on both sides of the first fin structure in the width direction are selectively removed. If a single semiconductor structure includes more than two first semiconductor portions, it is required to not only selectively remove the edge portions on both sides of the first fin structure in the width direction, but also selectively remove a middle region of the first fin structure in the width direction.

In addition, as shown in FIG. 6, it is possible to leave part of the first sacrificial layer 23 with reduced thickness at bottom of the open trench 26. Alternatively, when the second semiconductor portion is located at bottom of two adjacent first semiconductor portions, a full thickness of the first sacrificial layer may be retained.

For example, as shown in FIG. 6, in a case that the first fin structure 22 further includes the second sacrificial layer 27 located on the first channel layer 24, the opening trench 26 further penetrates through the second sacrificial layer 27 after selectively removing at least the edge portions on both sides of the first fin structure 22 in the width direction.

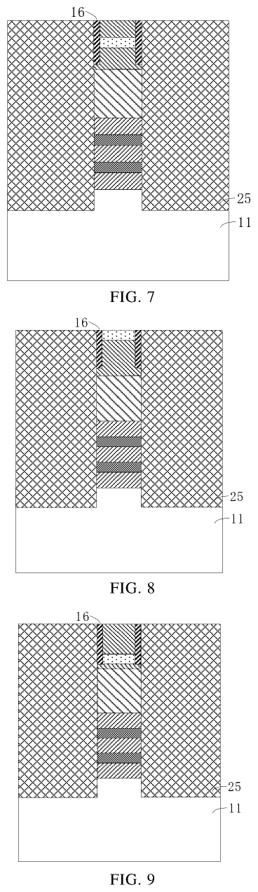

Next, as shown in FIG. 7 to FIG. 9, the first semiconductor portion 16 may be formed in the open trench 26 by processes such as epitaxy and planarization. A portion of the first channel layer 24 remaining between the two adjacent first semiconductor portions 16 acts as the second semiconductor portion 17.

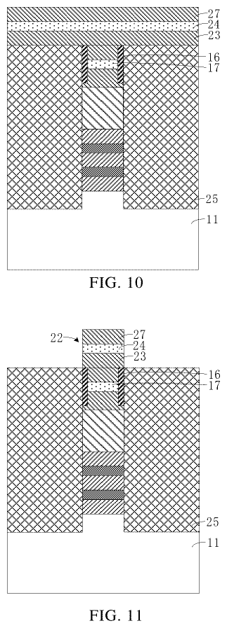

It should be noted that, in a case that the channel region includes a plurality of semiconductor structures, the method of manufacturing a semiconductor substrate further includes: before forming the first transistor based on a remaining portion of the first fin structure and the first semiconductor portion, as shown in FIG. 10 to FIG. 15, repeating an operation of sequentially forming the first fin structure 22, the first mask 25, the open trench 26 and the first semiconductor portion 16 until a number of layers of first semiconductor portions 16 formed on the semiconductor substrate 11 is equal to a number of layers of semiconductor structures 15 in the channel region 14. Two adjacent layers of the first semiconductor portions 16 are spaced by a portion of the first sacrificial layer 23 with reduced thickness.

Next, as shown in FIG. 16 to FIG. 28, the first transistor 12 is formed based on the first fin structure 22 and the first semiconductor portion 16. The gate stack 13 included in the first transistor 12 surrounds the periphery of the channel region 14. The channel region 14 includes at least one semiconductor structure 15, and each semiconductor structure 15 includes the first semiconductor portion 16 and the second semiconductor portion 17. In the semiconductor structure 15, at least one of surfaces of the second semiconductor portion 17 distributed oppositely in the thickness direction of the semiconductor substrate 11 is recessed inward relative to a corresponding one of surfaces of the first semiconductor portion 16 distributed oppositely in the thickness direction of the semiconductor substrate 11. Each of the first semiconductor portion 16 and the second semiconductor portion 17 is in contact with the source region 18 and the drain region 19 included in the first transistor 12, respectively.

The specific method for manufacturing the first transistor based on the first fin structure and the first semiconductor portion may be configured according to practical requirements, and is not specifically limited herein.

For example, as shown in FIG. 17 and FIG. 18, at least part of the first mask 25 in a thickness direction of the first mask may be selectively removed by processes such as dry etching or wet etching, so as to expose a bottom portion of the first sacrificial layer 23.

If the shallow trench isolation structure is manufactured based on the first mask, it is possible to remove just a part of the first mask. Alternatively, the first mask may be completely removed.

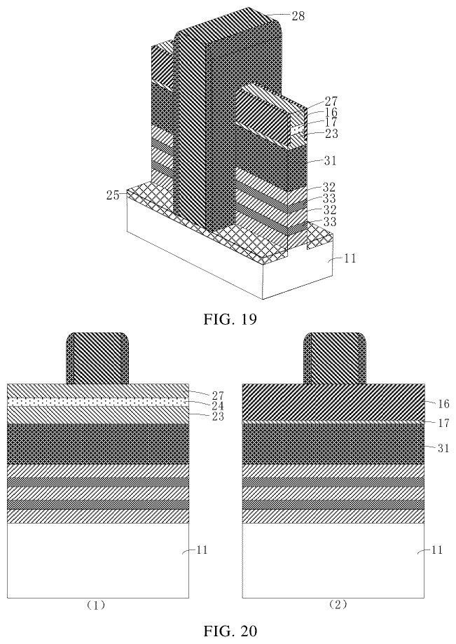

Next, as shown in FIG. 19 and FIG. 20, a second mask structure 28 spanning the first fin structure 22 may be formed by processes such as deposition and etching. Specific structure and material of the second mask structure 28 may be set according to practical requirements, as long as the second mask structure 28 may effectively function as a protective mask in subsequent processes.

For example, as shown in FIG. 19 and FIG. 20, the second mask structure 28 may include a sacrificial gate. The sacrificial gate may include an easily removable material such as polysilicon.

For example, the above-mentioned second mask structure may further include a gate oxide layer and a sacrificial gate located on the gate oxide layer. The gate oxide layer may include a material such as silicon oxide.

For example, as shown in FIG. 19 and FIG. 20, the second mask structure 28 may include a sacrificial gate and a gate spacer at least located on both sides of the sacrificial gate in the length direction. For a material of the gate spacer, reference may be made to the above description.

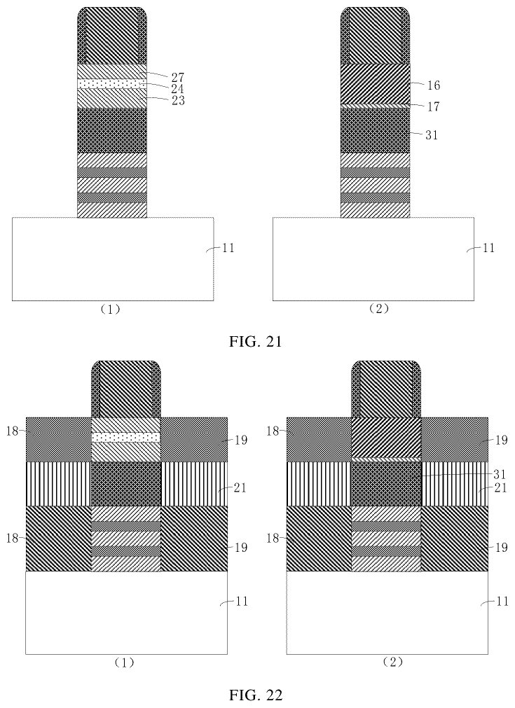

Next, as shown in parts (1) and (2) of FIG. 21, a portion of the first fin structure 22 and a portion of the first semiconductor portion 16 exposed from the second mask structure 28 may be selectively removed by processes such as dry etching or wet etching.

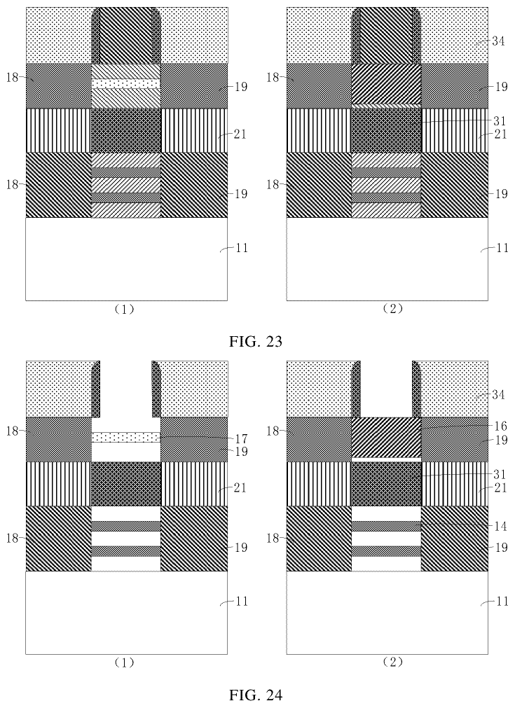

Next, as shown in FIG. 22, the source region 18 and the drain region 19 included in the first transistor 12 may be formed on both sides of a remaining portion of the first fin structure 22 and a first semiconductor portion 16, respectively.

Next, as shown in parts (1) and (2) of FIG. 23, the insulating dielectric layer 34 covering the semiconductor substrate 11 may be formed by processes such as deposition and planarization. The top of the insulating dielectric layer 34 is flush with the top of the second mask structure 28. For the material of the insulating dielectric layer 34, reference may be made to the above description.

Next, as shown in parts (1) and (2) of FIG. 24, at least part of the second mask structure 28 may be selectively removed by processes such as dry etching or wet etching. At least a remaining portion of the first sacrificial layer is removed, so that the remaining portion of the first semiconductor portion 16 and the second semiconductor portion 17 form the channel region 14.

To be noted, it is possible to determine whether to completely remove the second mask structure according to the specific structure of the second mask structure. For example, when the second mask structure includes the sacrificial gate, or includes the sacrificial gate and the gate oxide layer, the second mask structure may be completely removed. For example, when the second mask structure includes the sacrificial gate and the gate spacer, only the sacrificial gate may be removed, that is, part of the second mask structure may be removed.

Next, as shown in FIG. 25 to FIG. 28, the gate stack 13 surrounding the periphery of the channel region 14 may be formed by processes such as atomic layer deposition.

In an example, in a case that the manufactured semiconductor device further includes a second transistor and a first isolation structure, as shown in FIG. 1 to FIG. 3, a second fin structure 29 and a semiconductor isolation structure 30 may be formed on the semiconductor substrate 11 while the first fin structure 22 is formed on the semiconductor substrate 11. In the thickness direction of the semiconductor substrate 11, the semiconductor isolation structure 30 and the first fin structure 22 are sequentially disposed on the second fin structure 29. Furthermore, the method of manufacturing a semiconductor device further includes: as shown in FIG. 4 to FIG. 28, forming the second transistor 20 based on the second fin structure 29; and forming a first isolation structure 21 between the source region 18 included in the first transistor 12 and the source region 18 included in the second transistor 20 and between the drain region 19 included in the first transistor 12 and the drain region 19 included in the second transistor 20, respectively.

Specifically, specific structure of the second fin structure may be determined according to a device type of the second transistor and a structure of the channel region included in the second transistor, and will not be specifically limited here.

For example, when the second transistor is a fin field-effect transistor, the second fin structure may be a single-layer strip-shaped structure. In this case, a material of the second fin structure is any semiconductor material different from the material of the first sacrificial layer (or the material of the second sacrificial layer).

For another example, when the second transistor is a gate-all-around transistor, as shown in FIG. 2, the second fin structure 29 may include a third sacrificial layer 32 and a second channel layer 33 alternately stacked. In the second fin structure 29, the bottom layer and the top layer are both the third sacrificial layers 32. The material of the second channel layer 33 may be determined according to the material of the channel region 14 included in the second transistor 20. The material of the third sacrificial layer 32 may be any semiconductor material different from the material of the first channel layer 24 and the material of the second channel layer 33.

As for the semiconductor isolation structure, a region in which the first isolation structure is formed may be released subsequently by removing a portion of the semiconductor isolation structure exposed from the second mask structure. In addition, a region in which the second isolation structure is formed may be released subsequently by removing a portion of the semiconductor isolation structure covered by the second mask structure. Therefore, a thickness of the semiconductor isolation structure may be determined according to sizes of the first isolation structure and the second isolation structure. The material of the semiconductor isolation structure may be any semiconductor material different from the material of the first channel layer, the material of the first sacrificial layer, the material of the second channel layer and the material of the third sacrificial layer (when the first fin structure further includes the second sacrificial layer, a material different from the material of the second sacrificial layer is also required).

In an actual manufacturing process, when removing at least part of the first mask after the first fin structure, the second fin structure and the semiconductor isolation structure are simultaneously formed on the semiconductor substrate, a bottom of the second fin structure needs to be exposed if the second fin structure is located below the first fin structure. The bottom portion of the first sacrificial layer at the bottom layer needs to be exposed if the first fin structure is located below the second fin structure. Then, when forming the second mask structure, the second mask structure needs to span the semiconductor isolation structure and the second fin structure. Next, if the manufactured semiconductor device further includes the second isolation structure, it is desired to selectively remove the semiconductor isolation structure, and then form the second isolation structure in the released region. Subsequently, when selectively removing the portion of the first fin structure exposed from the second mask structure, it is also desired to remove a portion of the second fin structure and a portion of the semiconductor isolation structure (if the second isolation structure is formed, the second isolation structure is selectively etched here) exposed from the second mask structure. After that, the source region and the drain region included in the first transistor are formed on both sides of a remaining portion of the first fin structure by processes such as epitaxy, and the second transistor is formed on both sides of a remaining second fin structure. Furthermore, after forming the source region and the drain region located on the bottom layer, the first isolation structure is formed thereon.

It should be noted that, for the convenience of describing the manufacturing process of the second transistor, FIG. 1 to FIG. 28 in embodiments of the present disclosure are drawn by taking the second transistor as an example, which does not mean that the semiconductor device provided in embodiments of the present disclosure must include the second transistor. In addition, FIG. 1 to FIG. 28 show one possible method of manufacturing the second transistor, which does not mean that the second transistor may only be formed by this method. How to form the second transistor is not a main focus of embodiments of the present disclosure. Therefore, in the specification, the second transistor has only briefly been introduced, so that those skilled in the art may easily implement embodiments provided by the present disclosure. Those skilled in the art may completely imagine other methods to manufacture the second transistor.

The beneficial effects of the second aspect and its various implementations in embodiments of the present disclosure may be understood with reference to the analysis of the beneficial effects of the first aspect and its various implementations, and will not be repeated here.

In the above-mentioned description, the technical details such as patterning and etching of each layer have not been described in detail. However, those skilled in the art should understand that various technical means may be used to form layers, regions, etc. of desired shapes. In addition, in order to form the same structure, those skilled in the art may further design a method that is not exactly the same as the method described above. In addition, although the various embodiments have been described above separately, this does not mean that the measures in the various embodiments may not be advantageously used in combination.

Embodiments of the present disclosure have been described above. However, the examples are for illustrative purposes only, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

What is claimed is:

1. A semiconductor device, comprising: a semiconductor substrate and a first transistor disposed on the semiconductor substrate; wherein the first transistor comprises a gate stack surrounding a periphery of a channel region;
the channel region comprises at least one semiconductor structure; in a width direction of the channel region, each semiconductor structure comprises at least two first semiconductor portions arranged at intervals and a second semiconductor portion disposed between every two adjacent first semiconductor portions; in the semiconductor structure, at least one of surfaces of the second semiconductor portion distributed oppositely in a thickness direction of the semiconductor substrate is recessed inward relative to a corresponding one of surfaces of the first semiconductor portion distributed oppositely in the thickness direction of the semiconductor substrate; and in a length direction of the channel region, each of the first semiconductor portion and the second semiconductor portion is in contact with a source region and a drain region comprised in the first transistor.

2. The semiconductor device according to claim 1, wherein a height of the first semiconductor portion is greater than a height of the second semiconductor portion.

3. The semiconductor device according to claim 1, wherein a width of the second semiconductor portion is greater than a width of the first semiconductor portion.

4. The semiconductor device according to claim 1, wherein a crystal orientation of the first semiconductor portion is a [110] crystal orientation.

5. The semiconductor device according to claim 1, wherein a crystal orientation of the second semiconductor portion is a [100] crystal orientation.

6. The semiconductor device according to claim 1, wherein the first transistor is a P-type transistor.

7. The semiconductor device according to claim 1, wherein in the semiconductor structure, the second semiconductor portion is suspended between every two adjacent first semiconductor portions.

8. The semiconductor device according to claim 1, wherein the semiconductor structure is H-shaped.

9. The semiconductor device according to claim 1, wherein in a case that the channel region comprises a plurality of semiconductor structures, different semiconductor structures are distributed at intervals in the thickness direction of the semiconductor substrate; and the gate stack surrounds a periphery of each semiconductor structure.

10. The semiconductor device according to claim 1, wherein the semiconductor device further comprises a second transistor and a first isolation structure; the first transistor and the second transistor are distributed at an interval in the thickness direction of the semiconductor substrate; and the first isolation structure is disposed between the source region comprised in the first transistor and a source region comprised in the second transistor and between the drain region comprised in the first transistor and a drain region comprised in the second transistor.

11. The semiconductor device according to claim 10, wherein in the width direction of the channel region, at least the semiconductor structure located at bottom of the first transistor has a sidewall substantially aligned with a sidewall of a channel region comprised in the second transistor.

12. A method of manufacturing a semiconductor device, comprising:
forming a first fin structure on a semiconductor substrate, wherein the first fin structure comprises at least a first sacrificial layer and a first channel layer located on the first sacrificial layer;
forming a first mask on sidewalls of the first fin structure to surround a periphery of the first fin structure;
selectively removing at least edge portions on both sides of the first fin structure in a width direction of the first fin structure, so as to form an open trench, wherein the open trench penetrates through at least the first channel layer, and at least part of the first sacrificial layer with reduced thickness is retained at bottom of the open trench;
forming a first semiconductor portion in the open trench, wherein a portion of the first channel layer remaining between two adjacent first semiconductor portions acts as a second semiconductor portion; and
forming a first transistor based on the first fin structure and the first semiconductor portion, wherein the first transistor comprises a gate stack surrounding a periphery of a channel region; the channel region comprises at least one semiconductor structure, and each semiconductor structure comprises the first semiconductor portion and the second semiconductor portion; in the semiconductor structure, at least one of surfaces of the second semiconductor portion distributed oppositely in a thickness direction of the semiconductor substrate is recessed inward relative to a corresponding one of surfaces of the first semiconductor portion distributed oppositely in the thickness direction of the semiconductor substrate; and each of the first semiconductor portion and the second semiconductor portion is in contact with a source region and a drain region comprised in the first transistor.

13. The method of manufacturing a semiconductor device according to claim 12, wherein the first fin structure further comprises a second sacrificial layer located on the first channel layer; and
after selectively removing at least edge portions on both sides of the first fin structure in the width direction, the open trench further penetrates through the second sacrificial layer.

14. The method of manufacturing a semiconductor device according to claim 12, further comprising: in a case that the channel region comprises a plurality of semiconductor structures, before forming a first transistor based on a remaining portion of the first fin structure and the first semiconductor portion,
repeating an operation of sequentially forming the first fin structure, the first mask, the open trench and the first semiconductor portion until a number of layers of first semiconductor portions formed on the semiconductor substrate is equal to a number of layers of the semiconductor structures in the channel region, where two adjacent layers of the first semiconductor portions are spaced by a portion of the first sacrificial layer with reduced thickness.

15. The method of manufacturing a semiconductor device according to claim 13, further comprising: in a case that the channel region comprises a plurality of semiconductor structures, before forming a first transistor based on a remaining portion of the first fin structure and the first semiconductor portion,
repeating an operation of sequentially forming the first fin structure, the first mask, the open trench and the first semiconductor portion until a number of layers of first semiconductor portions formed on the semiconductor substrate is equal to a number of layers of the semiconductor structures in the channel region, where two adjacent layers of the first semiconductor portions are spaced by a portion of the first sacrificial layer with reduced thickness.

16. The method of manufacturing a semiconductor device according to claim 12, wherein the forming a first transistor based on the first fin structure and the first semiconductor portion comprises:
selectively removing at least part of the first mask in a thickness direction of the first mask, so as to expose a bottom of the first sacrificial layer;
forming a second mask structure spanning the first fin structure;
selectively removing a portion of the first fin structure and a portion of the first semiconductor portion exposed from the second mask structure, and forming the source region and the drain region comprised in the first transistor on both sides of a remaining portion of the first fin structure and a remaining portion of the first semiconductor portion, respectively;
selectively removing at least part of the second mask structure, and removing at least a remaining portion of the first sacrificial layer, so that the remaining portion of the first semiconductor portion and the second semiconductor portion form the channel region; and
forming the gate stack surrounding the periphery of the channel region.

17. The method of manufacturing a semiconductor device according to claim 12, wherein a second fin structure and a semiconductor isolation structure are formed on the semiconductor substrate while forming the first fin structure on the semiconductor substrate; and in the thickness direction of the semiconductor substrate, the semiconductor isolation structure and the first fin structure are sequentially disposed on the second fin structure; and
the method of manufacturing the semiconductor device further comprises: forming a second transistor based on the second fin structure; and forming a first isolation structure between the source region comprised in the first transistor and a source region comprised in the second transistor and between the drain region comprised in the first transistor and a drain region comprised in the second transistor, respectively.
